(19) United States
(12) Patent Application Publication
(10) Pub. No.: US 2009/0163255 A1
(43) Pub. Date: Jun. 25, 2009

(54) HIDDEN PICTURE CUSTOMIZATION FOR CELLULAR TELEPHONES

(75) Inventor: John Thomas Sadler, Wake Forest, NC (US)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 11/962,226

(22) Filed: Dec. 21, 2007

(51) Int. Cl. H04M 1/02; H05K 5/00

(52) U.S. Cl. 455/575.1

(57) ABSTRACT

A mobile phone having a housing or portion thereof that is configured to receive and retain a user insertable image such that the image is viewable by a user. In an embodiment, the image is concealed from view under certain conditions. In the absence of such conditions the image can be viewed by the user. The housing or portion thereof appears similar to any other portion of the housing of the phone except when the image is viewable. The housing or portion thereof can be configured to conceal a regular photograph, for example. Thus, the invention allows economical customization of a phone with unique images without having to provide an additional electronic display. Existing phones can be retrofitted, for example, with a battery cover (or other removable member) embodying the features of the invention.

### TECHNICAL FIELD OF THE INVENTION

The present invention relates generally to electronic equipment and, more particularly, to a hidden image for a mobile phone.

### DESCRIPTION OF THE RELATED ART

Consumer demand for a particular mobile phone is typically driven by the functional features of the mobile phone and the design of the mobile phone. Conventional mobile phones now provide many features in addition to providing voice communication capabilities. For example, mobile phones can be used to surf the internet, transmit and receive messages (e.g., emails and text messages), play music and videos, take and display photographs, as well as a number of other features. As mobile phones become ubiquitous, even the most basic mobile phones now offer such extended capabilities and, thus, the design and/or aesthetic appeal of the phone become important in driving demand.

Consumers often are willing to spend more on a phone with a unique look or design. For example, very thin phones have become popular. Another popular design that offers both a unique look and functionality is a slide phone. Slide phones typically have a hidden keypad that slides out when needed. Phones having a unique finish, such as chrome, also offer a unique look that can be appealing to certain potential customers.

Regardless of the functionality or design of a phone, every phone typically has a display and/or buttons consuming a first side of the phone, for example the top (or front) surface of the phone. Typically, the opposite side of the phone, for example the bottom (or back) surface of the phone, is plain in comparison to the side of the phone having the display. The bottom of the phone often also includes an access panel for accessing a battery of the mobile phone.

### SUMMARY

The present invention provides a mobile phone having a housing or portion thereof that is configured to receive and retain a user insertable image such that the image is viewable by a user. In an embodiment, the image is concealed from view under certain conditions. In the absence of such conditions the image can be viewed by the user. The housing or portion thereof appears similar to any other portion of the housing of the phone except when the image is viewable. The housing or portion thereof can be configured to conceal a regular photograph, for example. Thus, the invention allows economical customization of a phone with unique images without having to provide an additional electronic display. Existing phones can be retrofitted, for example, with a battery cover (or other removable member) embodying the features of the invention.

One aspect of the technology relates to an electronic device comprising a housing configured to receive and retain a user insertable image within the housing adjacent a portion of the housing that is at least partially transparent such that the image is viewable by the user under at least certain viewing conditions.

According to another aspect, the device further comprises a metallic layer covering the portion of the housing that is at least partially transparent, the metallic layer operable to conceal the user insertable image within the housing except under certain viewing conditions during which the metallic layer is at least partially transparent thereby exposing the user insertable image to view from an exterior of the housing.

According to another aspect, the metallic layer is operative to reflect ambient light under some conditions and to transmit light under other conditions.

According to another aspect, the metallic layer is vacuum deposited on a surface of the housing.

According to another aspect, the housing includes a removable portion.

According to another aspect, the removable portion of the housing is a battery cover, and the battery cover includes the transparent material having the metallic layer.

According to another aspect, the housing is configured to receive and retain a user insertable image that is fixed on a tangible medium.

According to another aspect, the housing is configured to receive and retain a user insertable image that is a photograph.

According to another aspect, the user insertable image is at least partially translucent, and the device further comprises a backlight configured to illuminate the user insertable image to thereby make the image visible through the metallic layer.

According to another aspect, the backlight is an LED.

According to another aspect, the device further comprises circuitry for activating the backlight in response to the occurrence of a predetermined event.

According to another aspect, wherein the electronic equipment is a mobile phone.

According to another aspect, the electronic equipment is at least one of a personal audio device, a personal video device or a personal digital assistant.

According to another aspect, a user exchangeable cover removably attachable to a housing of an electronic device comprises a body configured to receive and retain a user insertable image adjacent a portion of the body that is at least partially transparent such that the image is viewable by the user under at least certain viewing conditions.

According to another aspect, the cover further comprises a metallic layer covering the portion of the body that is at least partially transparent, the metallic layer operable to conceal the user insertable image within the housing except under certain viewing conditions during which the metallic layer is at least partially transparent thereby exposing the user insertable image to view from an exterior of the housing.

According to another aspect, the metallic layer is operative to reflect ambient light under some conditions and to transmit light under other conditions.

According to another aspect, the metallic layer is vacuum deposited on a surface of the body.

According to another aspect, the cover is a battery cover for covering a battery compartment of a mobile phone.

According to another aspect, the image is a user insertable image, and the body includes at least one retention tab for engaging an edge of the user insertable image.

According to another aspect, the user insertable image is at least partially translucent, and the cover further comprises a backlight supported by the body and configured for illuminating the image to thereby make the image visible through the metallic layer.

According to another aspect, the backlight is an LED.

According to another aspect, the cover further comprises circuitry for activating the backlight in response to the occurrence of a predetermined event.

According to another aspect, the body is configured to receive and retain a user insertable image that is fixed on a tangible medium.

According to another aspect the housing is configured to receive and retain a user insertable image that is a photograph.

To the accomplishment of the foregoing and the related ends, the invention, then, comprises the features hereinafter fully described in the specification and particularly pointed out in the claims, the following description and the annexed drawings setting forth in detail certain illustrative embodiments of the invention, these being indicative, however, of but several of the various ways in which the principles of the invention may be suitably employed.

Other systems, methods, features, and advantages of the invention will be or become apparent to one with skill in the art upon examination of the following drawings and detailed description. It is intended that all such additional systems, methods, features, and advantages be included within this description, be within the scope of the present invention, and be protected by the accompanying claims.

Although the invention is shown and described with respect to one or more embodiments, it is to be understood that equivalents and modifications will occur to others skilled in the art upon the reading and understanding of the specification. The present invention includes all such equivalents and modifications, and is limited only by the scope of the claims.

Also, although the various features are described and are illustrated in respective drawings/embodiments, it will be appreciated that features of a given drawing or embodiment may be used in one or more other drawings or embodiments of the invention.

It should be emphasized that the term “comprise/comprising” when used in this specification is taken to specify the presence of stated features, integers, steps or components but does not preclude the presence or addition of one or more other features, integers, steps, components or groups thereof.”

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Likewise, elements and features depicted in one drawing may be combined with elements and features depicted in additional drawings. Moreover, in the drawings, like reference numerals designate corresponding parts throughout the several views.

FIG. 1 is an illustration of an exemplary mobile phone.

FIG. 2 is an illustration of the back of the phone of FIG. 1 having an exemplary housing in accordance with the invention.

FIG. 3 is the phone of FIG. 2 with a user insertable image within the housing visible in accordance with the invention.

FIG. 4 is an illustration of an exemplary battery cover in accordance with the invention.

FIG. 5 is an illustration of the reverse side of the battery cover of FIG. 4.

FIG. 6 is a cross-sectional view of the battery cover taken along the line 6-6 in FIG. 4.

### DETAILED DESCRIPTION OF EMBODIMENTS

The present invention will now be described with reference to the drawings, wherein like reference numerals are used to refer to like elements throughout.

The term “electronic equipment” and/or “electronic device” includes portable radio communication equipment. The term “portable radio communication equipment,” which herein after is referred to as a “mobile radio terminal,” “mobile phone,” “mobile device,” or “mobile terminal”, and the like, includes all equipment such as mobile telephones, pagers, communicators, i.e., electronic organizers, personal digital assistants (PDAs), smartphones, portable communication apparatus or the like.

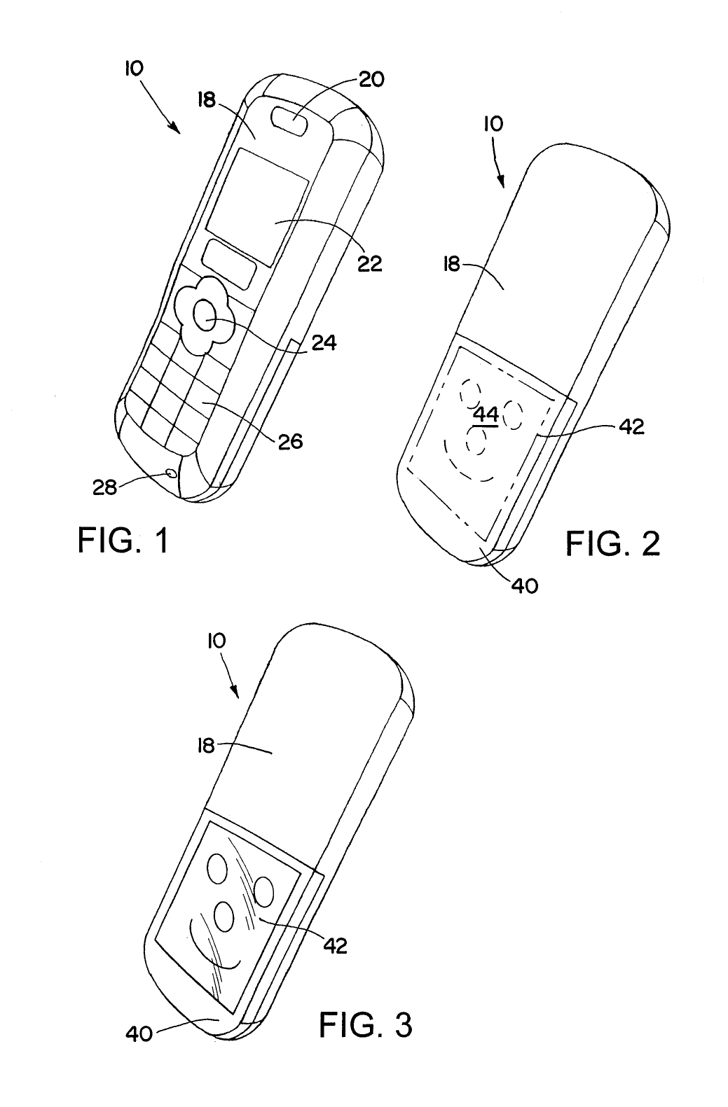

Referring now to FIG. 1, a mobile phone 10 is shown as having a “brick” or “block” design type housing 18 (sometimes referred to as a case), but it will be appreciated that other type housings, such as, for example, clam shell or slide-type housings, may be utilized without departing from the scope of the invention. The mobile phone 10 further includes a speaker 20, display 22, a navigation switch and selection/function keys or switches 24, a key pad 26, and a microphone 28; these are illustrative and exemplary of parts of a typical mobile phone, but it will be appreciated that other parts that are similar or different in form and/or function may be included in the mobile phone 10. The mobile phones to which the invention pertains also may be of the types that have more or fewer functions, keys, etc., compared to those illustrated and described herein.

As will be appreciated, the mobile phone 10 may function as a conventional mobile phone. The mobile phone 10 may have additional functions and capabilities that may be developed in the future. From a conventional point of view, the display 22 displays information to a user, such as operating state, time, phone numbers, contact information, various navigational menus, etc., which facilitate and/or enable the user to utilize the various features of the mobile phone. The display also may be used to view movies, images, or to play games, for example. Part or all of the display 22 may be a touch screen type device. The navigation and function keys 24 and the keypad 26 may be conventional in that they provide for a variety of user operations. For example, one or more of the function keys and navigation device 24 may be used to navigate through a menu displayed on the display 22 to select different phone functions, profiles, settings, etc., as is conventional. The keypad 26 typically includes one or more special function keys, such as, a “call send” key for initiating or answering a call, a “call end” key for ending or hanging up a call, and dialing keys for dialing a telephone number. Other keys included in the navigation and function keys 24 and/or keypad 26 may include an on/off power key, a web browser launch key, a camera key, a voice mail key, a calendar key, etc.

Turning now to FIGS. 2 and 3, and in accordance with the invention, the reverse side of the phone 10 is illustrated having a housing 18 that includes a battery cover 40. As is conventional, the battery cover 40 serves to cover a battery (not shown) found within the housing 18. A user may remove the battery cover 40 in order to access the battery for replacement and the like.

The battery cover 40 can be configured with rails, grooves, tabs, etc. (not shown) for mating with corresponding rails, grooves, tabs, etc. (also not shown) of the housing 18 for securing the battery cover 40 in place in a conventional manner. Of course, the battery cover 40 can be secured to the housing 18 in a wide variety of manners, and the particular manner in which the battery cover 40 is secured is not germane to the invention.

In addition, however, the battery cover 40 in accordance with the invention is configured to retain a user insertable image 42 within the housing 18. The user insertable image 42, which is shown in phantom in FIG. 2, can be a photograph, a drawing, or the like and can be viewable through a transparent portion of the battery cover 40.

In accordance with the exemplary illustrated embodiment, the battery cover 40 is configured to conceal the image 42 from view under certain viewing conditions (FIG. 2), and to permit viewing of the image 42 under other viewing conditions. For example, in FIG. 2 the orientation of the phone 10 is such that light incident to the battery cover 40 is reflected off the battery cover 40 such that the image 42 is not visible through the battery cover 40. In FIG. 3, however, the orientation of the phone 10 is such that light incident to the battery cover 40 passes through the battery cover by which the image 42 is illuminated and thereby becomes viewable through the battery cover 40. This feature of the battery cover 40 provides a unique manner in which a phone can be customized with an image 42.

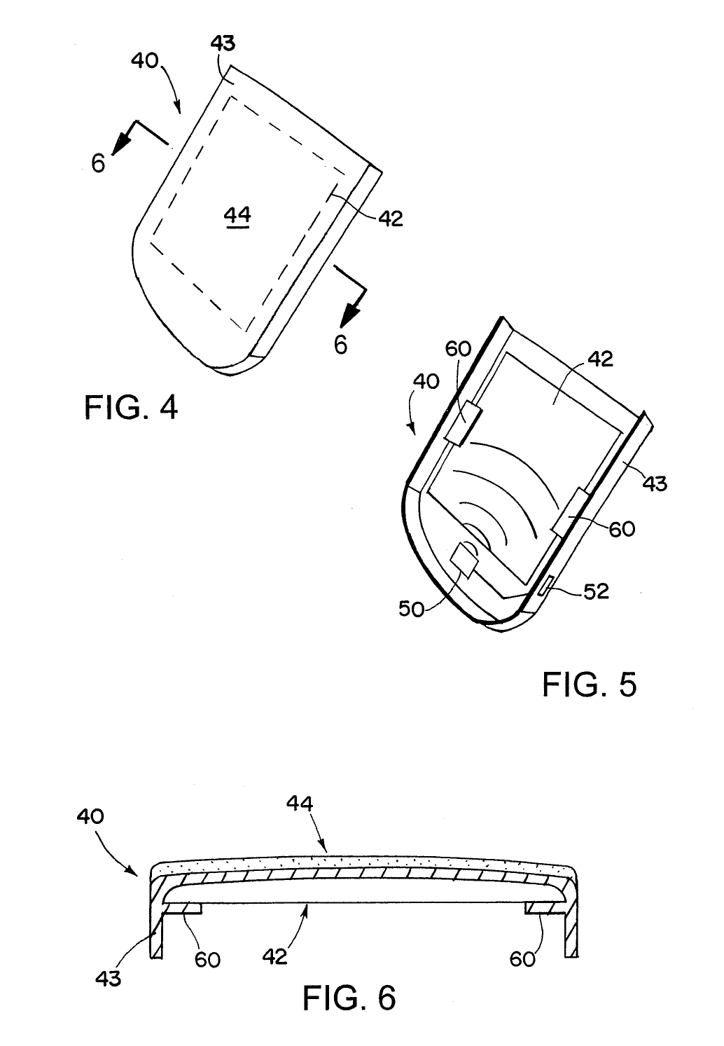

In order to provide this feature, and with reference to FIGS. 4-6, the battery cover 40 includes a body 43 having a metallic layer 44 deposited on at least a portion of a surface thereof via vacuum metallization (or other suitable process). At least a portion of the battery cover 40 having the metallic layer 44 is a made of a clear plastic (or other clear material) such that the image 42 is visible through the battery cover under certain conditions. The metallic layer 44 can comprise any suitable metal such as aluminum or chrome, for example. Typically, the housing 18 will also include a metallic layer such that the housing 18 and the battery cover 40 together generally provide a uniform appearance, except when the image 42 is visible through the battery cover 40.

As will be appreciated, the metallic layer 44 is at least partially reflective under a variety of lighting conditions. The degree to which the metallic layer 44 is reflective (or transparent) is due at least in part to the thickness of the metallic layer 44 and/or the amount of reflective material in the metallic layer 44. Accordingly, it will be appreciated that the metallic layer 40 can be configured to produce a desired appearance, while still allowing the image to be visible under certain conditions.

The metallic layer 44 generally will conceal the image 42 from view except under certain conditions. One condition under which the image 42 is visible generally exists when light is reflected off of the image 42. Such light can pass through the battery cover 40 when the angle of incidence of the light on the outer surface of the battery cover 40 is such that the light passes through the battery cover 40 (e.g., refracted rather than reflected). This can occur, for example, when the phone is held at a particular angle with respect to a light source.

Another possibility is the provision of a light for illuminating the user insertable image 42 thereby causing the image 42 to be visible through the battery cover 40. In FIG. 5, a backlight 50 is schematically illustrated supported by the battery cover 40. The backlight 50 can be a simple LED, for example. The backlight can be configured to illuminate the user insertable image 42 such that it can be seen through the battery cover. In this regard, the image 42 generally must be at least partially translucent such that light from the backlight 50 can pass therethrough. A diffuser may be provided to distribute the light evenly behind the image 42. A backlight battery separate from the battery of the phone can also be provided as part of the backlight 50. Alternatively, the backlight can be powered, via suitable connections, by the battery of the phone. A switch can be provided for manually activating the backlight. For example, backlight switch 52 as shown in FIG. 5. As will be appreciated, a front light can also be provided for illuminating the face of the image 42, in which case the image 42 need not be at least partially translucent.

Other arrangements of activating the backlight can be configured. For example, the backlight can be configured to activate upon application of pressure to the battery cover 40. In this regard, a pressure sensitive switch can be provided on the battery cover 40. Suitable circuitry can also be provided for activating the backlight upon the occurrence of certain events. For example, the backlight 50 can be configured to illuminate during a phone call as often, depending on how the user holds the phone, the user insertable image 42 would be viewable by others. Also, the backlight may be configured not to illuminate when the phone is in a certain position, such as when the phone is resting on a table, as such an orientation of the phone would typically preclude a user or others from seeing the user insertable image 42 even if the backlight is activated. The backlight may also be configured to activate simply when the user presses any button of the phone.

The battery cover 40 further can include a retention device for retaining the user insertable image 42. For example, and as illustrated in FIG. 5, a pair of retention tabs 60 can be provided for retaining opposite edges of a photograph.

Turning to FIG. 6, the battery cover is shown in cross-section. In this view, it is apparent that the body of the battery cover 40 is generally U-shape in cross-section. The metallic layer 44 is deposited on the outer surface of the battery cover 40 opposite the user insertable image 42. As will be appreciated, however, the metallic layer 44 could also be deposited on the inner surface of the battery cover 40 adjacent the user insertable image 42.

It will be appreciated that, although the invention has been shown and described in the context of a battery cover for a mobile phone, aspects of the invention are equally applicable to other types of devices and covers and/or housing components. By way of example, features of the invention can be included in a cover that is removably securable to a cell phone, for example. Such a cover could be a protective cover that surrounds and protects the phone by providing cushioning and/or scratch protection to the cell phone. Such a cover could include the metallic layer provided over a transparent portion thereof through which an image could be selectively viewable depending on the lighting conditions. The image could be an electronic image produced by a display, such as an LCD display for example, or user insertable image such as a photograph or drawing, for example.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. An electronic device comprising a housing configured to receive and retain a user insertable image within the housing adjacent a portion of the housing that is at least partially transparent such that the image is viewable by the user under at least certain viewing conditions.

2. An electronic device as set forth in claim 1, further comprising a metallic layer covering the portion of the housing that is at least partially transparent, the metallic layer operable to conceal the user insertable image within the housing except under certain viewing conditions during which the metallic layer is at least partially transparent thereby exposing the user insertable image to view from an exterior of the housing.

3. An electronic device as set forth in claim 2, wherein the metallic layer is operative to reflect ambient light under some conditions and to transmit light under other conditions.

4. An electronic device as set forth in claim 3, wherein the metallic layer is vacuum deposited on a surface of the housing.

5. An electronic device as set forth in claim 2, wherein the portion of the housing that is at least partially transparent is part of a removable portion of the housing in which the user insertable image is inserted and retained.

6. An electronic device as set forth in claim 5, wherein the removable portion of the housing is a battery cover and includes the metallic layer.

7. An electronic device as set forth in claim 1, wherein the housing includes a removable portion in which the user insertable image is inserted and retained.

8. An electronic device as set forth in claim 1, wherein the housing is configured to receive and retain a user insertable image that is fixed on a tangible medium.

9. An electronic device as set forth in claim 1, wherein the housing is configured to receive and retain a user insertable image that is a photograph.

10. An electronic device as set forth in claim 1, wherein the user insertable image is at least partially translucent, and further comprising a backlight configured to illuminate the user insertable image to thereby make the image visible through the metallic layer.

11. An electronic device as set forth in claim 10, wherein the backlight is an LED.

12. An electronic device as set forth in claim 10, further comprising circuitry for activating the backlight in response to the occurrence of a predetermined event.

13. An electronic equipment as set forth in claim 1, wherein the electronic equipment is a mobile phone.

14. An electronic equipment as set forth in claim 1, wherein the electronic equipment is at least one of a personal audio device, a personal video device or a personal digital assistant.

15. A user exchangeable cover removably attachable to a housing of an electronic device, comprising a body configured to receive and retain a user insertable image adjacent a portion of the body that is at least partially transparent such that the image is viewable by the user under at least certain viewing conditions.

16. A user exchangeable cover as set forth in claim 15, further comprising a metallic layer covering the portion of the body that is at least partially transparent, the metallic layer operable to conceal the user insertable image within the housing except under certain viewing conditions during which the metallic layer is at least partially transparent thereby exposing the user insert able image to view from an exterior of the housing.

17. A cover as set forth in claim 16, wherein the metallic layer is operative to reflect ambient light under some conditions and to transmit light under other conditions.

18. A cover as set forth in claim 16, wherein the metallic layer is vacuum deposited on a surface of the body.

19. A cover as set forth in claim 15, wherein the cover is a battery cover for covering a battery compartment of a mobile phone.

20. A cover as set forth in claim 15, wherein the body includes at least one retention tab for engaging an edge of the user insertable image.

21. A cover as set forth in claim 15, wherein the user insertable image is at least partially translucent, and further comprising a backlight supported by the body and configured for illuminating the image to thereby make the image visible through the metallic layer.

22. A cover as set forth in claim 21, wherein the backlight is an LED.

23. A cover as set forth in claim 21, further comprising circuitry for activating the backlight in response to the occurrence of a predetermined event.

24. A cover as set forth in claim 15, wherein the body is configured to receive and retain a user insertable image that is fixed on a tangible medium.

25. A cover as set forth in claim 15, wherein the housing is configured to receive and retain a user insertable image that is a photograph.
